(19) United States
(12) Patent Application Publication
(10) Pub. No.: US 2007/0104000 A1
(43) Pub. Date: May 10, 2007

(54) Field programmable memory repair for eprom

(75) Inventors: Qing Lin, San Jose, CA (US); Kiran Dasoju, Milpitas, CA (US)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Broadcom Corporation

(21) Appl. No.: 11/589,164

(22) Filed: Oct. 30, 2006

Related U.S. Application Data
(60) Provisional application No. 60/735,211, filed on Nov. 10, 2005.

(51) Int. Cl. G11C 29/00

(52) U.S. Cl. 365/200

(57) ABSTRACT

The present invention according to certain embodiments is directed to a method, device and apparatus for repairing a plurality of memory locations. The present invention includes providing a plurality of memory locations, providing a plurality of fuses coupled to the memory locations and loading fuse data into a data register from a plurality of read-only memory (ROM) devices thereby creating loaded fuse data. The present invention also provides loading a programming sequence of the memory device, wherein the programming sequence includes a plurality of memory addresses, and reading the loaded fuse data from the fuse register to a plurality of memory locations corresponding to the plurality of memory addresses.

### CROSS-REFERENCE TO RELATED APPLICATIONS

This application claims priority of U.S. Provisional Patent Application Ser. No. 60/735,211 filed on Nov. 10, 2005. The subject matter of this earlier filed application is hereby incorporated by reference.

### BACKGROUND OF THE INVENTION

1. Field of the Invention

The invention relates to a method and apparatus for repairable memory scheme.

2. Description of the Related Art

A switching system may include one or more network devices, such as a Ethernet switching chip, each of which includes several modules that are used to process information that is transmitted through the device.

Highly integrated, high performance components such as memory structures, require complex fabrication and manufacturing processes. These processes may experience unavoidable parameter defects that can impose unwanted physical defects on the units being produced. Redundancy is added or built into memory structures to enhance yield, hopefully providing a one-for-one replacement for a failed part or subsystem. As the memory cells continue to push design limits, the overall yield per memory cell unit area tends to decrease.

In memory repair schemes, fuse data and or a fuse register is directed to data held by the fuse or memory repair (for example repair data).

It should be appreciated that blowing a fuse using a laser device or electric pulse is a one-time operation. Once the laser programmable or electronically one-time programmable fuse is blown, it cannot revert to its original state.

### BRIEF DESCRIPTION OF THE DRAWINGS

For the present invention to be easily understood and readily practiced, various embodiments will now be described, for purposes of illustration and not limitation, in conjunction with the following figures:

FIG. 1 is an illustration of a network device in which an embodiment of the present invention may be implemented;

FIG. 2 illustrates an overview of the memory repair scheme according to the an exemplary embodiment of the present invention;

FIG. 3 illustrates a schematic of an exemplary embodiment of the invention;

FIG. 4 a flow diagram of some of the functions supported by the present invention; and

FIG. 5 illustrates yet another exemplary embodiment of the present invention.

### DETAILED DESCRIPTION

Specifically, the device includes an ingress module, a Memory Management Unit (MMU) and an egress module. The ingress module includes switching functionality for determining to which destination port a packet should be directed. The MMU is used for storing packet information and performing resource checks. The egress module is used for performing packet modification and for transmitting the packet to at least one appropriate destination port. One of the ports on the device may be a CPU port that enables the device to send and receive information to and from external switching/routing control entities or CPUs. Some devices also include a CPU processing module through which the device interfaces with external CPU ports.

As packets enter the device from multiple ports, they are forwarded to the ingress module where switching and other processing are performed on the packets. Thereafter, the packets are transmitted to the MMU. After performing resource checks on the packets, the MMU transmits the packets to the egress module for further processing and modification. Thereafter, the egress module transmits the packets to at least one destination port, including a CPU port. If the packets are being transmitted to the CPU port, the egress module forwards them through a CPU processing module which transmits the packet to the CPU via the PCI bus.

Each of the ingress module, the MMU, and the egress module includes one or more internal Random Access Memory (RAM) and Content Addressable Memory (CAM) for storing information. For example, the ingress and egress modules may store lookup tables with switching information in the internal RAM/CAM. When the device is initialized, information is stored in each RAM and/or CAM. During normal processing, the information in one or more RAM/CAM may be updated either by the device or by the CPU. To synchronize the information stored in the RAM/CAM with the information stored on the CPU, the CPU may need to access and/or update the information stored in one or more RAM and/or CAM. Previous designs enabled the CPU to obtain all of the information from a RAM/CAM in a bulk transfer operation, i.e., read all of the information at one time. However, these designs provided no bulk transfer write operations from the CPU to the device. Moreover, the bulk read transfer operation was only available on some tables.

As such, if the CPU had to insert and/or delete an entry in a RAM and/or CAM, a table DMA engine in the CPU processing module copied all entries from the table to the CPU. Upon modifying the table, the CPU transmitted one entry at a time to the RAM/CAM to be modified. For a RAM/CAM with a large amount of entries, this operation is not only slow, it is costly since numerous write operations are required in order to update one entry in the RAM/CAM.

Many memory devices store and retrieve data by addressing specific memory locations. As a result, this path often becomes the limiting factor for systems that rely on fast memory access. The time required to find an item stored in memory can be reduced considerably if the stored data item can be identified for access by the content of the data itself rather than by its address. Memory that is accessed in this way is called content-addressable memory (CAM).

One of the quickest methods of table searching uses CAM searching wherein all table entries are compared against a search key at the same time, and the search result is delivered to an output instantly. However, in CAM searching there is typically a limit to the size of comparison fields (i.e. data width) and the size of payload fields which may be used in CAM searching.

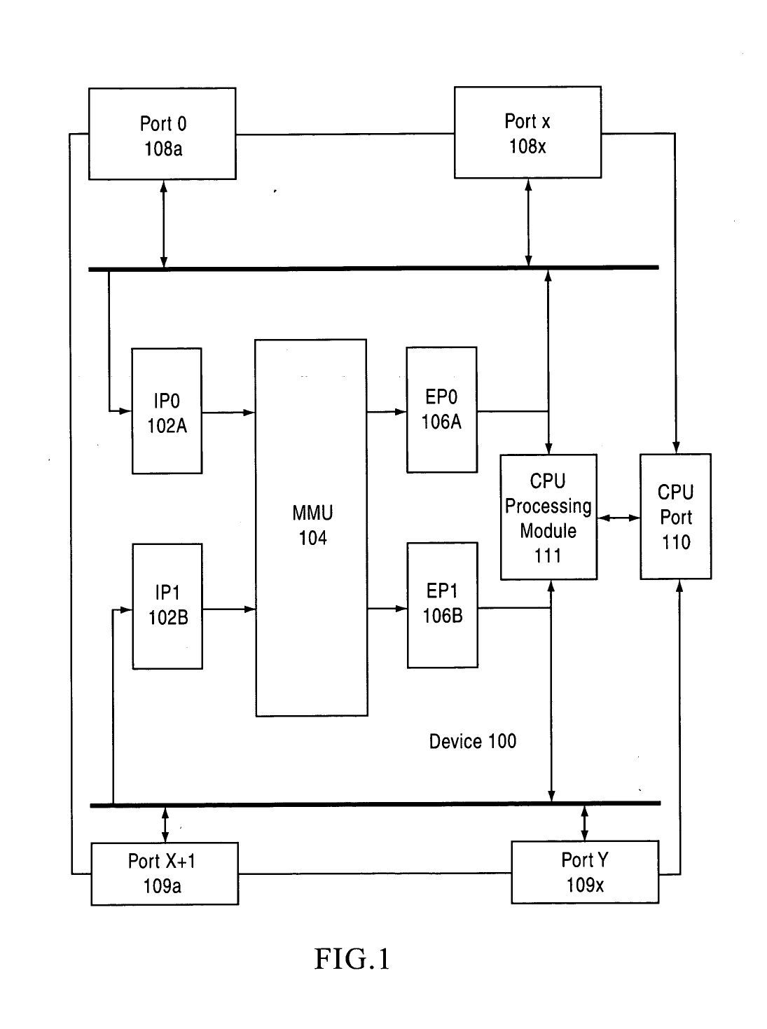

FIG. 1 illustrates a network device, such as a switching chip, in which an embodiment the present invention may be implemented. Device 100 includes ingress modules 102A and 102B, a MMU 104, and an egress modules 106A and 106B. Ingress modules 102A and 102B are used for performing switching functionality on an incoming packet. MMU 104 is used for storing packets and performing resource checks on each packet. Egress modules 106A and 106B are used for performing packet modification and transmitting the packet to an appropriate destination port. Each of Ingress modules 102A, 102B, MMU 104 and Egress modules 106A and 106B include multiple cycles for processing instructions generated by that module. Device 100 implements a pipelined approach to process incoming packets. The key to the performance of device 100 is the ability of the pipeline to process one packet every clock.

Device 100 may also include one or more internal fabric high speed ports Port0-Portx 108a-108x for example a HiGig port, or more external Ethernet ports and a CPU port 110. High speed ports 108a-108x are used to interconnect various network devices in a system and thus form an internal switching fabric for transporting packets between external source ports and one or more external destination ports. As such, high speed ports 108a-108x are not externally visible outside of a system that includes multiple interconnected network devices. CPU port 110 is used to send and receive packets to and from external switching/routing control entities or CPUs. Device 100 interfaces with external/off-chip CPUs through a CPU processing module 111, such as a CMIC, which interfaces with a PCI bus that connects device 100 to an external CPU.

Network traffic enters and exits device 100 through external ports 109a-109x. Specifically, traffic in device 100 is routed from an external source port to one or more unique destination ports. In one embodiment of the invention, device 100 supports physical Ethernet ports and logical (trunk) ports. A physical Ethernet port is a physical port on device 100 that is globally identified by a global port identifier. In an embodiment, the global port identifier includes a module identifier and a local port number that uniquely identifies device 100 and a specific physical port. The trunk ports are a set of physical external Ethernet ports that act as a single link layer port. Each trunk port is assigned a global a trunk group identifier (TGID). According to an embodiment, device 100 can support up to 128 trunk ports, with up to 8 members per trunk port, and up to 29 external physical ports.

Once a packet enters device 100 on a source port 109a-109i, the packet is transmitted to ingress module 102 for processing. Packets may enter device 100 from a XBOD or a GBOD. The XBOD is a block that has one 10GE/12G MAC and supports packets from high speed ports 108a-108x. The GBOD is a block that has 12 10/100/1G MAC and supports packets from ports 109a-109i.

It can be appreciated that exemplary embodiments of the present invention are directed to a device, which includes but is not limited to, a switch, router or bridge.

According to certain embodiments the present invention utilizes a direct mapped scheme between fuse data and one-time-programmable (OTP) storage bit. One fuse pin for a repairable memory corresponds to one bit in OTP storage space. Fuse registers are connected into a single data chain to allow fuse data stored in OTP to be read and shifted into for auto load. According to an exemplary embodiment of the invention, the shifting of the chain is done at ⅓ speed to allow pipeline registers to be added between two elements of the fuse data chain. During chip initialization, fuse data in OTP will be loaded into fuse data chain to enable the redundant row of the repaired memory if programmed. The programming of OTP is performed one bit at a time. The PCI register sends the program command with the corresponding address and OTP at set up. Once the program is completed, a verify operation is launched to verify the correctness of program. Besides PCI interface, JTAG interface is used to monitor the status of OTP operation.

It should be appreciated that it is useful to describe various aspects and embodiments of the invention herein, in the context of an SRAM memory structure, using CMOS SRAM memory cells. However, it should be further appreciated by those skilled in the art that the present invention is not limited to CMOS-based processes and that these aspects and embodiments may be used in memory products other than a SRAM memory structure, including without limitation, DRAM, ROM, PLA and the like whether embedded in a system or a stand alone memory device.

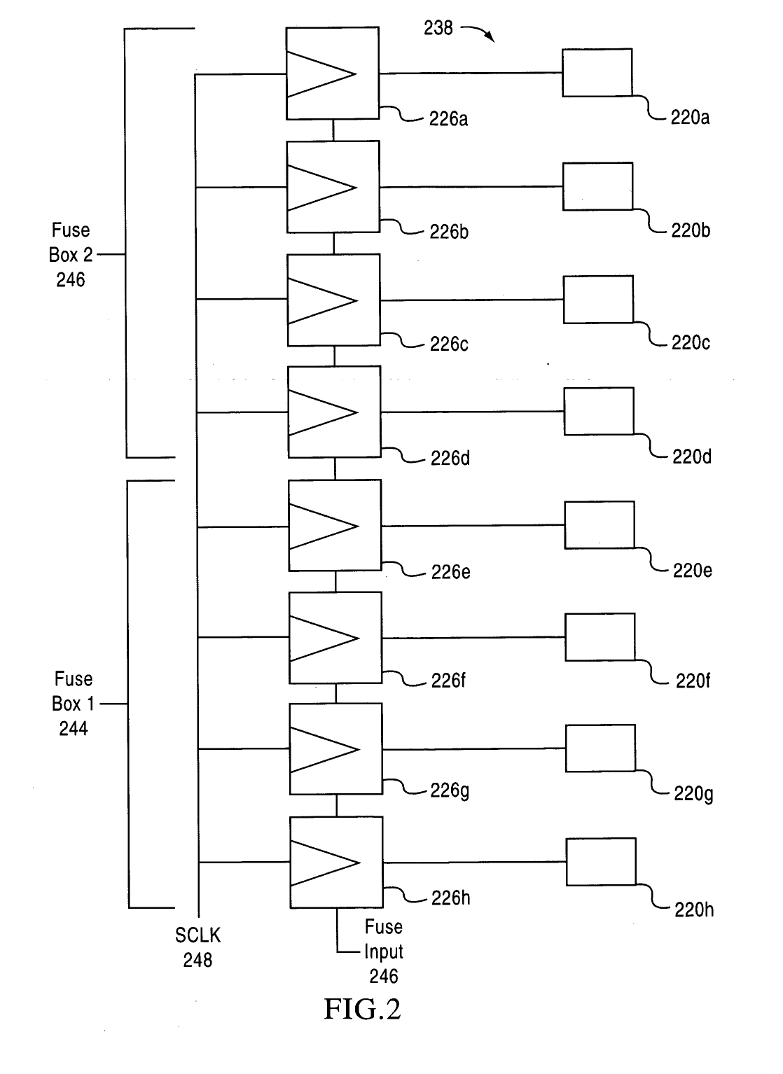

FIG. 2 illustrates an embodiment of the present invention wherein the plurality of registers 226a-226h and fuses 220a -220h are used for row redundancy in a cell array 238. Similarly, a plurality of registers 226 and fuses 220 may be used for column redundancy in a cell array 238 or some combination of row and column redundancy, where the registers 226 are chained to the same shift register. Moreover, the present invention is not dependent on any particular type of fuse. According to other exemplary embodiments of the invention, an encoding or address matching scheme is utilized to map the bit in the OTP storage space, to a fuse pin in the repairable memory. The advantage of these embodiments is that the size of the memory repair data storage space may be significantly reduced.

Fuse Box 1 244 and Fuse Box 2 246 are further illustrated in FIG. 2. Chaining the registers to the fuses results in one clock input for shifting data and one data input pin interfaces. It should be appreciated that two external pins, one for serial fuse data 246 and one for a shift clock 248 are utilized. All of the fuse inputs 246 may be chained on to shift register 242 so that the required fuse data may be shifted in.

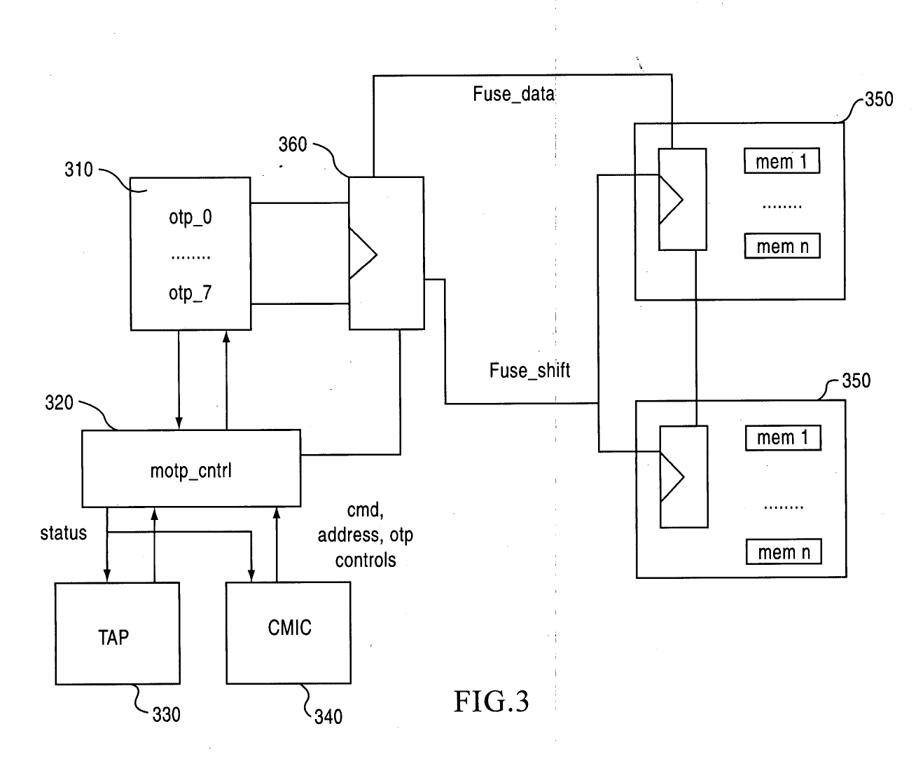

FIG. 3 illustrates a system block diagram of according to an exemplary embodiment of the present invention. The system includes otp 0-otp 7 310 which are required to store the fuse information for repairable memories. The fuse data fuse_data is from a shift register 360 and transmitted to a device sub-block the repairable memories 350. The shift register 360 also controls the shifting of data to the shift registers of subblock 350. The motp_cntrl block 320 manages control of the otp operations and interfaces with CPU Processing Module (cmic) 330 and a 1149.1 compliant JTAG controller (TAP) 340.

It can be appreciated that the present invention can be implemented as a computer program, a remote device or a transportable device.

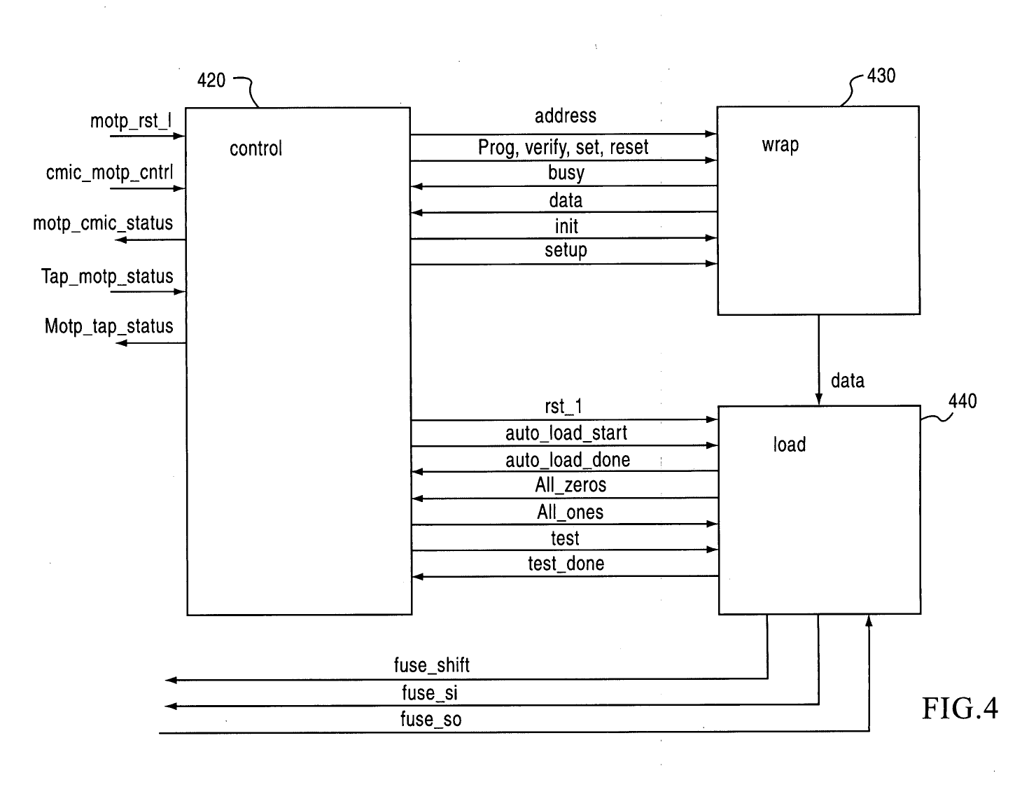

FIG. 4 illustrates further detail of the motp_contrl block illustrated in FIG. 3. The motp_cntrl (control) block 420 includes the master control state machine, (illustrated in FIG. 7) which processes OTP operation request from cmic or tap, generates proper controls for auto load and otp program/verify/set/reset and read operations.

According to an exemplary embodiment of the invention the motp module 410 consists of three blocks, motp_cntrl 420, motp_load 430 and otp_wrapper 440. The otp_wrapper block 440 initiates the OTPs that are required to store the fuse information for repairable memories.

The motp_cntrl block (control) 420 manages the control of OTP operations, and interfaces with cmic and TAP. The functions include but are not limited to:
Interface with cmic (PCI access) and TAP (JTAG access);
Auto load OTP content to block fuse registers during system initialization, perform checksum check during auto-load and report error;
Control programming sequence of OTP, program is done one bit at a time, followed by a verify sequence to validate the program;
Read OTP data from cmic/PCI. The read is done one bit at a time. During Read, a verify command is first performed to allow user to set otp timing control, such as vsel, then the data corresponding to the given address is read out.
Set/Reset test. In set test, OTP outputs are set to 1/0 using set/reset command of OTP. OTP data is then read out and checked by all_ones/all_zeros sticky registers in motp_load block. The all_ones/all_zeros status from motp_load block indicates if the pass/fail status of the test. Set/Reset test should not change the content of the fuse register; and
Control verify test sequence of OTPs. In the verify test, OTP data is read out and checked by all_ones/all_zeros registers in motp_load block. The verify test should not change the content of the fuse register.

The control block 420 sends the address for otp programming to the otp_wrap (wrap) block 430 which is verified by the control block. Further, the control block 420 via the init and setup signals, signals the otp_wrap block 430 to initialize and setup the OTP operations. The motp_cntrl block further signals to the motp_load (load) block 440 to begin the auto load process which is discussed below. Further, the control block 420 will perform a verification test of the loaded data. During a set test, otp outputs are set to 1/0 using the set/reset command of the otp. The otp data is then read out and checked by the all ones and all_zeros registers in the load block 340.

The motp_load block 440 handles the auto load of fuse data onto fuse registers after the above described tests and verifications are performed. The load block 440 shifts the fuse data into the fuse registers via the fuse_shift (control signal to enable the shifting operation of fuse register) line. Another signal fuse_si (send data onto the use register) from the load block 440 scans in the data shift onto the fuse register chain. The load block receives a signal fuse_so that scans out data from the fuse register chain. The fuse register output is returned to motp_load through the fuse_so signal.

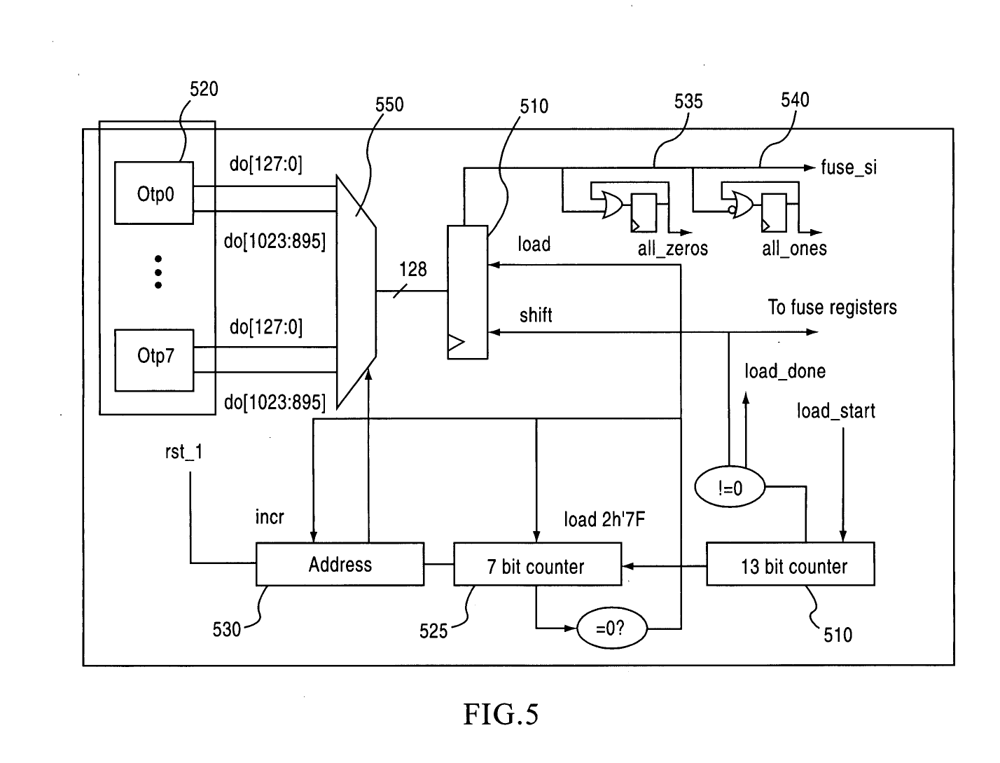

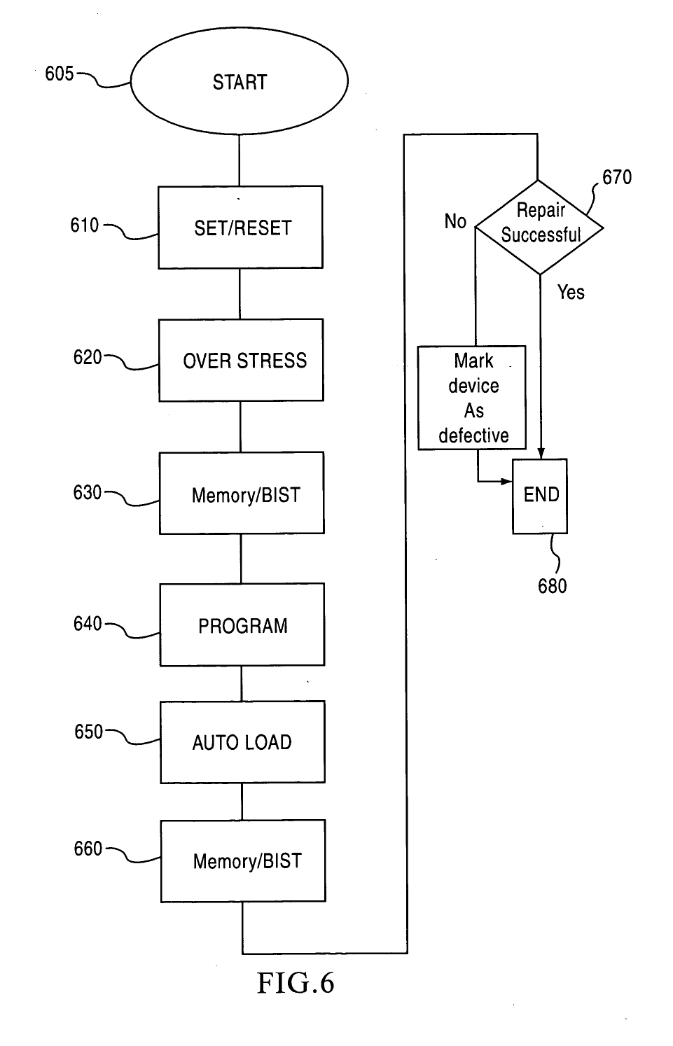

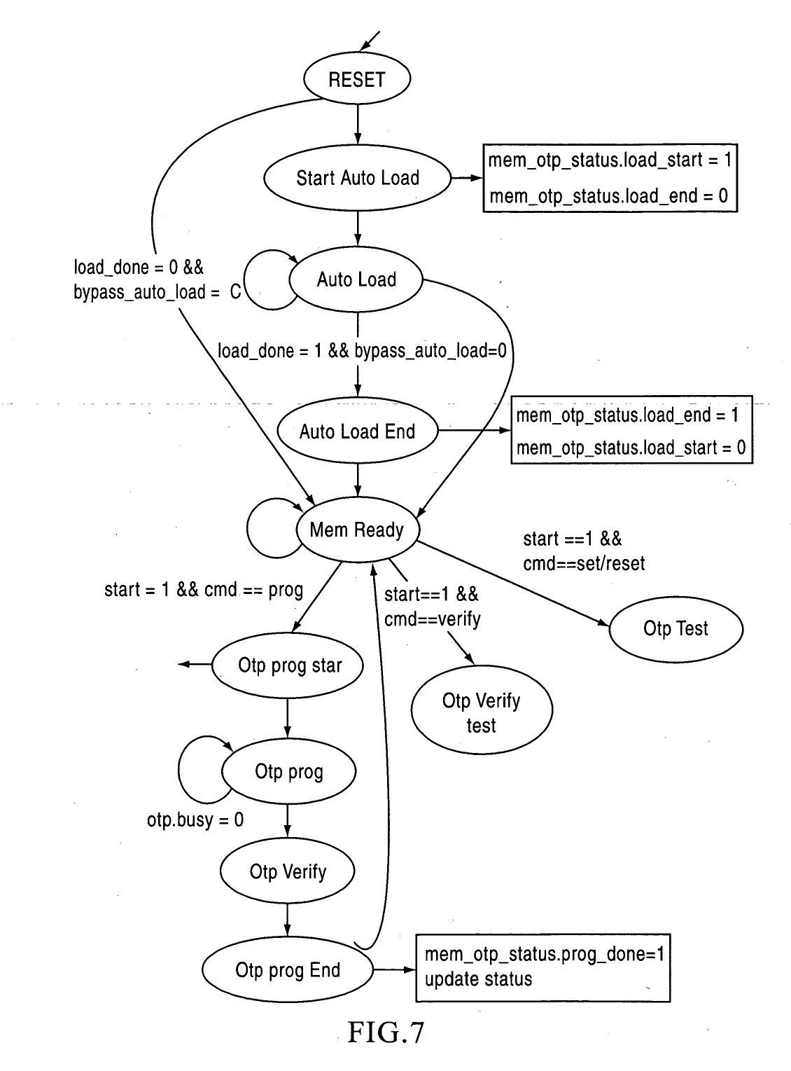

FIG. 5 illustrates the Mem OTP Auto Load function. Upon deassertion of rst_1, the mem otp master controller will start to perform the auto load of the fuse data stored in otps and shift fuse data onto fuse data registers. The read and shift of the entire contents of otps are broken into multiple reads and shifts, with 128 bits fuse data been read and shifted each time. The shift is done at ⅓ of the core clock frequency to ease timing requirement. The LSB bit of fuse data will be shifted onto fuse data chain first.

Each time the load_start is asserted, the 13 bit counter 510 is reset to total fuse data counts and the 128 bit shift register 515 starts shifting data into the fuse data chain. When the 13 bit counter 510 reaches 0, all fuse data stored in OTPs 520 have been shifted into fuse data registers. In another exemplary embodiment of the invention, an alternative way to detect the total length off use data chain is through shifting a fixed pattern into fuse data chain and count the number of shifting needed to see the pattern shifting out of the chain. This would avoid to hardcode a fixed fuse data chain length in the design, which is updated each time memory fuse pin count changes.

The 7-bit counter 525 is reset each time the 128-bit shift register 515 is loaded and is decremented each time the 128-bit shift register 515 is shifted. When it reaches 0, a load from OTPs 520 may be used. When operation begins, the address counter 530 is loaded with address 0, which corresponding to OTPO bit 0 to bit 127. After this, the address counter 530 will be incremented by 1 each time the 7-bit counter 525 reaches 1 (one cycle before load). Since the fuse data registers can be placed close to memory, which leads to long distance between current fuse register and next one along shift path, fuse shift is performed at ⅓ speed. The shift signal is asserted every three cycles during shift. Up to two pipeline registers can be placed between two fuse data registers to help the timing closure.

While shifting data onto fuse data chain, the shift data is checked using two sticky registers, one to monitor all zeros data condition, the other to monitor all ones data condition. As stated above, the all_zeros/all_ones status are used for two purposes, first to indicate if the otps have been programmed, second to check otp data in set and reset test. The sticky registers are reset to 0 when auto load or load test sequence start. Checksum verification of fuse data is also performed during auto-load. Checksum counter monitors and calculates the checksum of motp bits. When all motp data is loaded, the pre-programmed motp checksum is read and compared against the calculated checksum. The result is updated to checksum_error status bit. Motp preserve mtop MSB 13 bits for checksum of total motp bits. When motp cntrl sends test signal, the set/reset load test sequence starts. Data will be read through 128-bit register 515 and checked by the all zeros 535 and all_ones 540 sticky registers. In contrast to the auto load sequence, fuse_shift and fuse data remain inactive during the test, so that data will not be loaded into fuse registers. Once all otp data are read and checked, the test_done and all_zeros/all_ones status go back to motp_cntrl block to complete the set/reset test.

In accordance with an embodiment of the present invention, all of the fuse registers are connected into a single scan chain following memory built-in self test (BIST) grouping. The fuse registers module should be integrated at the top level of the block hierarchy. Fuse register fuse pin outputs should be connected to the corresponding repairable memory fuse pin inputs. According to an exemplary embodiment of the invention a debug mode for some subset of the fuse banks in which the fuse outputs can be sampled and controlled is implemented.

Through PCI interface, software can send commands to program, read and run set/reset and verify test for mtop. A TAP interface is used to debug and diagnose motp failure.

FIG. 6 is a flow diagram that illustrates an exemplary programming sequence for motp operations. The programming fields are for cmic_to_motp_cntrl_reg register, and the status fields are for motp_to_cmic_status_reg register.

Set/Reset tests 610 are used for an ATE manufacture test to check motp outputs stuck-at-0 and stuck-at-1 defects.

| | |
|---|---|
| 1. | chip reset and initialized, auto-load can be bypassed, and blocks |
| | can be kept in reset |
| 2. | set tm[2:0] 3′b000 (default) |
| 3. | set sadbyp = 0 (default) |
| 4. | set cmd[2:0] = 3′b100 (set) or 3′b101 (reset) |
| 5. | set start = 1 |
| 6. | wait and check done and go status for command done and complete |
| | status |
| 7. | check status bit all_zeros = 1 in reset test, check all_ones = 1 |
| | in set test. |

Next, an over current stress test (ocst) is used in conjunction with the burn-in test for qualification of otp 620. The ocst mode test is essentially a long read mode where the current is increased through the fuse. The test should be run after otp is programmed. The ocst is detailed below.

1. chip reset and initialized, auto-load can be bypassed, and blocks can be kept in reset

| | |
|---|---|
| 1. | chip reset and initialized, auto-load can be bypassed, and |
| | blocks can be kept in reset |
| 2. | set sadbyp = 1 |
| 3. | setup vsel[3:0] |
| 4. | set ocst = 1 |
| 5. | set cmd[2:0] = 3′b110 (ocst) |
| 6. | set start = 1 |
| 7. | leave ocst high for multiple clock cycles (TBD) |
| 8. | setocst = 0 |
| 9. | set sadbyp = 0 |
| 10. | check done and go status bit. |

Next, in the process according to this exemplary embodiment of the present invention the memoryBIST 630 is performed. There are two passes of memoryBist run in manufacture screen test. The first pass is run without memory otp programming. Below is the memoryBist sequence.

| | |
|---|---|
| 1. | assert pad_pci_rst_l, and supply pci clock |
| 2. | JTAG write to tap_to_motp_cntrl_reg register bit |
| | bypass_auto_load = 1 |
| 3. | JTAG read until p11(s) lock if p11 clock is needed for memoryBist |
| 4. | JTAG write to tap_deassert_reset = 1 to deassert block reset |
| 5. | JTAG write to start memoryBlST for the all blocks in parallel |
| 6. | JTAG read to check memoryBiST status |

For memories that fail the initial memoryBist run, failure data will be collected to decide if the memory is repairable and the required fuse setting to enable the redundant memory row(s). If the failing memory is repairable, motp programming will be performed to set the motp bits corresponding to the fuse pin setting and second pass of memoryBist will be run as follows.

| | |
|---|---|
| 1. | assert pad_pci_rst_l, and supply pci clock |
| 2. | JTAG read until p11(s) lock if p11 clock is needed for memoryBist |
| 3. | JTAG read until auto-load complete, check load_end and check- |
| | sum_error |
| 4. | JTAG write to tap_deassert_reset = 1 to deassert block reset |
| 5. | JTAG write to start memoryBlST for the all blocks in parallel |
| 6. | JTAG read to check memoryBlST status |

Next, the MOTP program portion 640 is performed to program one bit at a time for the giving address with the correct repair content provided. The otps are programmed with the fuse data. Further, checksum of the total programming bits is calculated externally, and the checksum is programmed into motp reserved checksum field after all motp bits have been programmed. The program process is detailed below.

| | |
|---|---|
| 1. | chip reset and initialized, auto-load can be bypassed, and blocks |
| | can be kept in reset. |
| 2. | set address to the bit position in motp |
| 3. | set pcount[2:0] = 3′b010 (default) |
| 4. | set progsel = 0 (default) |
| 5. | set cmd[2:0] = 3′b001 (program) |
| 6. | set start = 1 to start program sequence |
| 7. | wait prog_done and prog_end for completion of program sequence |

Next, auto-load is performed to load the repair data into the fuse register 650. The fuse data auto-load is outlined below.

| | |
|---|---|
| 1. | assert pci_rst_l to reset chip |
| | if bypass auto-load from tap, set tap to motp cntrl_reg by- |
| | pass_auto_load bit to 1. |
| 2. | deassert pci_rst_l, cmic pci domain out of reset |
| | if bypass auto-load from PCI, set cmic_to_motp_cntrl reg by- |
| | pass_auto_load bit to 1. |
| 3. | wait for PLL lock |
| 4. | PLL lock, otp reset deasserted, auto-load start |
| | If bypass_auto_load is set, go to step 7. |
| 5. | wait for auto-load complete, check if load_end status bit is set. |
| 6. | auto-load completed, load_end bit set to 1, check checksum_error |
| | status. |
| 7. | software block reset through PCI |

The Memory BIST test will be run again 660 to determine if the repair is successful 670. If the test was successful, the sequence will end 680. If the repair was not successful, the device will be indicated as a bad device.

In certain embodiments of the present invention a Read procedure is performed one bit at a time for a giving motp address. The Read procedure is a debug feature that is not used on normal operation.

| | |
|---|---|
| 1. | chip reset and initialized, auto-load can be bypassed, and blocks |
| | can be kept in reset |
| 2. | set address[12:0] to the address of the motp read bit |
| 3. | set tm[2:0] 3′b000 (default) |
| 4. | set sadbyp = 0 (deault) |
| 5. | set vsel[3:0] = 4′b0011 (default) |
| 6. | set cmd[2:0] 3′b000 (read) |
| 7. | set start = 1 |
| 8. | wait and check done and go status for command done and complete |
| | status |
| 9. | read data bit to get motp read data |

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

A method for memory field repair. The method includes storing fuse data, program and verify the repair module with repair fuse data. The method further includes loading the fuse data into fuse registers verify the repair module's programmed data.

What is claimed:

1. A method of repairing a memory device, the method comprising:
providing a plurality of memory locations;
providing a plurality of fuses coupled to the memory locations;
loading fuse data into a data register from a plurality of read-only memory (ROM) devices thereby creating loaded fuse data;
loading a programming sequence of the memory device, wherein the programming sequence includes a plurality of memory addresses; and
reading the loaded fuse data from the fuse register to a plurality of memory locations corresponding to the plurality of memory addresses.

2. A method of repairing a memory device according to claim 1, further comprising:
performing a test to determine an address of a failed memory location of the plurality of memory locations,
wherein if a failed memory location is detected, further determining if the defective memory location is repairable, and
if the defective memory location is repairable, program the fuse data into the fuse memory locations, and
loading fuse data into the defective memory location at the address of the defective memory location.

3. A method of repairing a memory device according to claim 2, further comprising:
performing a first test to monitor whether the fuse data can be set to all ones; and
performing a second test to monitor whether the fuse data can be set to all zeros.

4. A method of repairing a memory device according to claim 1, further comprising:
performing a verification test, wherein the verification test indicates whether all of the fuses are operational

5. A method of repairing a memory device according to claim 3, wherein the reading step is performed one bit at a time.

6. A device for repairing at least one of a plurality of memory locations, the apparatus comprising:
a plurality of memory locations wherein the memory locations have addresses;
a plurality of fuses coupled to the memory locations;
a control block, that controls operation of the apparatus and obtaining memory repair data;
a wrap block coupled to the control block, that initiates a plurality of read-only memory (ROM) devices required to store fuse information for repairable memories;
a load block, coupled to the wrap block, that loads fuse data into the plurality of ROM devices and thereby providing loaded fuse data; and
a fuse register block including a plurality of fuse registers, that receives the loaded fuse data from the plurality of ROM devices, wherein the fuse data is forwarded to a corresponding plurality of memory locations.

7. A device according to claim 6, wherein the fuse register block comprises a plurality of fuse registers connected into a single data chain.

8. A device for repairing at least one memory device according to claim 7, further comprising a shift register, wherein the shift register forwards the loaded fuse data to the fuse register block and provides a signal to shift the fuse data through the data chain.

9. A device for repairing at least one memory device according to claim 8, further comprising a built-in self test (BIST) unit coupled to the input of the plurality of fuse registers, wherein the BIST unit is configured to perform a test of the memory to determine an address of a failed memory location of the plurality of memory locations.

10. A device for repairing at least one memory device according to claim 9, wherein each fuse of the plurality of fuses includes a bit for identifying if the fuse is enabled.

11. An apparatus for repairing at least one of a plurality of memory locations, the apparatus comprising:
a plurality of memory locations wherein the memory locations have addresses;
a plurality of fuses coupled to the memory locations;
a control means for controlling operation of the apparatus and obtaining memory repair data;
an intiation means coupled to the control block for initiating a plurality of read-only memory (ROM) devices required to store fuse information for repairable memories;
a loading means coupled to the wrap block, for loading fuse data into the plurality of ROM devices and thereby providing loaded fuse data; and
a fuse register block including a plurality of fuse registers, that receives the loaded fuse data from the plurality of ROM devices, wherein the fuse data is forwarded to a corresponding plurality of memory locations.

12. An apparatus for repairing at least one memory device according to claim 6, wherein the fuse register block comprises a plurality of fuse registers connected into a single data chain.

13. An apparatus for repairing at least one memory device according to claim 7, further comprising a shift register, wherein the shift register forwards the loaded fuse data to the fuse register block and provides a signal to shift the fuse data through the data chain.

14. An apparatus for repairing at least one memory device according to claim 8, further comprising a means for performing a built-in self test (BIST), coupled to the input of the plurality of fuse registers, wherein the BIST unit is configured to perform a test of the memory to determine an address of a failed memory location of the plurality of memory locations.

15. An apparatus for repairing at least one memory device according to claim 9, wherein each fuse of the plurality of fuses includes a bit for identifying if the fuse is enabled.

16. A computer program embodied on a computer readable medium, the computer program for causing a processor to perform the following steps.
providing a plurality of memory locations;
providing a plurality of fuses coupled to the memory locations;
loading fuse data into a data register from a plurality of read-only memory (ROM) devices thereby creating loaded fuse data;
loading a programming sequence of the memory device, wherein the programming sequence includes a plurality of memory addresses; and
reading the loaded fuse data from the fuse register to a plurality of memory locations corresponding to the plurality of memory addresses.

17. A computer program according to claim 16, further comprising:
performing a test to determine an address of a failed memory location of the plurality of memory locations,
wherein if a failed memory location is detected, further determining if the defective memory location is repairable, and if the defective memory location is repairable, loading fuse data into the defective memory location at the address of the defective memory location.

18. A computer program according to claim 17, further comprising:
performing a first test to monitor whether the fuse data contains all ones; and
performing a second test to monitor whether the fuse data contains all zeros.

19. A computer program according to claim 16, further comprising:
performing a verification test, wherein the verification test indicates whether all of the fuses are operational

20. A computer program according to claim 17, wherein the reading step is performed one bit at a time.
